(19) United States
(12) Patent Application Publication
(10) Pub. No.: US 2025/0255135 A1
(43) Pub. Date: Aug. 7, 2025

(54) PIXEL ARRANGEMENT STRUCTURE, DISPLAY PANEL, AND MASK ASSEMBLY

(71) Applicant: Yungu (Gu’an) Technology Co., Ltd., Langfang (CN)

(72) Inventors: Lan LAN, Langfang (CN); Yi QU, Langfang (CN); Bo JIANG, Langfang (CN); Dandan FENG, Langfang (CN)

(73) Assignee: Yungu (Gu’an) Technology Co., Ltd., Langfang (CN)

(21) Appl. No.: 19/185,156

(22) Filed: Apr. 21, 2025

Related U.S. Application Data
(63) Continuation of application No. PCT/CN2023/084333, filed on Mar. 28, 2023.

(30) Foreign Application Priority Data
Oct. 27, 2022 (CN) 202211330400.X

(51) Int. Cl. H10K 59/35; H10K 59/131

(52) U.S. Cl. CPC H10K 59/353; H10K 59/131

(57) ABSTRACT

The present application provides a pixel arrangement structure, a display panel. The pixel arrangement structure includes a pixel unit. The pixel unit includes a first pixel group, a second pixel group, and a third pixel group that are arranged around a virtual center point. The first pixel group includes a plurality of first sub-pixels arranged around a first virtual point, the second pixel group includes a plurality of second sub-pixels arranged around a second virtual point, and the third pixel group includes a plurality of third sub-pixels arranged around a third virtual point. An orthographic projection of a first sub-pixel located closest to the virtual center point in a first direction is located between projections of two second sub-pixels in the first direction.

### CROSS-REFERENCE TO RELATED APPLICATIONS

This application is a continuation of International Application No. PCT/CN 2023/084333 filed on Mar. 28, 2023, which claims priority to Chinese Patent Application No. 202211330400.X, filed on Oct. 27, 2022, both of which are hereby incorporated by reference in their entireties.

### FIELD

The present application relates to the field of display devices, and in particular, to a pixel arrangement structure, a display panel, and a mask assembly.

### BACKGROUND

An organic light-emitting diode (OLED) is an active light-emitting device. Compared with a conventional liquid crystal display (LCD) method, an OLED display technology does not require a backlight and has a self-luminescence characteristic. The OLED uses a thin film layer of an organic material and a glass substrate. When a current passes through the film layer of the organic material, the organic material emits light. Therefore, an OLED display panel can significantly save power, can be made lighter and thinner, withstands a wider range of temperature changes than an LCD display panel, and has a larger viewing angle. The OLED display panel is expected to become the next generation of flat panel display technology after LCD, and is currently one of the flat panel display technologies that have attracted most attention.

### SUMMARY

Embodiments of the present application provide a pixel arrangement structure, a display panel, and a mask assembly, which can alleviate a diffraction problem.

One embodiment of the present application provides a pixel arrangement structure, including a pixel unit. The pixel unit includes a first pixel group, a second pixel group, and a third pixel group that are arranged around a virtual center point. The first pixel group includes a plurality of first sub-pixels arranged around a first virtual point, the second pixel group includes a plurality of second sub-pixels arranged around a second virtual point, and the third pixel group includes a plurality of third sub-pixels arranged around a third virtual point.

In the pixel unit, an orthographic projection of a first sub-pixel located closest to the virtual center point in a first direction is located between projections of two second sub-pixels in the first direction, and an orthographic projection of a second sub-pixel located closest to the virtual center point in a second direction is located between projections of two third sub-pixels in the second direction, where the first direction intersects with the second direction.

One embodiment of the present application further provides a pixel arrangement structure, including a plurality of repeatedly arranged pixel units. The pixel unit includes a first pixel group, a second pixel group, and a third pixel group around a virtual center point.

The first pixel group includes a plurality of first sub-pixels, and the plurality of first sub-pixels are spaced apart around a first virtual point to form a first transparent region centered on the first virtual point among the plurality of first sub-pixels.

The second pixel group includes a plurality of second sub-pixels, and the plurality of second sub-pixels are spaced apart around a second virtual point to form a second transparent region centered on the second virtual point among the plurality of second sub-pixels.

The third pixel group includes a plurality of third sub-pixels, and the plurality of third sub-pixels are spaced apart around a third virtual point to form a third transparent region centered on the third virtual point among the plurality of third sub-pixels.

The first pixel group, the second pixel group, and the third pixel group are arranged separately to form a wiring region among them.

One embodiment of the present application provides a display panel, including the pixel arrangement structure in any one of the above embodiments.

One embodiment of the present application provides a mask assembly. The mask assembly is configured to form the pixel arrangement structure in any one of the above embodiments through vapor deposition. The mask assembly includes:
a first mask. The first mask includes a first mask opening adapted to the first pixel group. The first mask opening is configured as a communicating shape corresponding to all the plurality of first sub-pixels in the first pixel group, or the first mask opening includes a plurality of sub-openings respectively corresponding to the plurality of first sub-pixels in the first pixel group.

The embodiments of the present application provide a pixel arrangement structure, a display panel, and a mask assembly. In a single pixel unit, in a first direction, an orthographic projection of a first sub-pixel is sandwiched between projections of two second sub-pixels. Moreover, in a second direction, an orthographic projection of a second sub-pixel is sandwiched between projections of two third sub-pixels. Compared with a conventional matrix pixel arrangement manner, this design makes it difficult to form a regular straight-line region between adjacent pixel groups, which means it is difficult to form regular straight slits between electrodes corresponding to the pixel arrangement structure, thereby reducing a degree of diffraction and improving a display effect of a corresponding display panel.

### BRIEF DESCRIPTION OF THE DRAWINGS

In order to describe the embodiments of the present application more clearly, the accompanying drawings required for illustration of the embodiments of the present application will be briefly described below. The accompanying drawings described below show merely some of the embodiments of the present application, and other drawings from the accompanying drawings may be derived without creative efforts.

FIG. 1 is a schematic diagram of a pixel arrangement structure according to an embodiment of the present application;

FIG. 2 is a schematic diagram of a structure of a pixel unit in a pixel arrangement structure according to an embodiment of the present application;

FIG. 3 is a schematic diagram of a structure of another pixel unit in a pixel arrangement structure according to an embodiment of the present application;

FIG. 4 is a schematic diagram of a structure of another pixel unit in a pixel arrangement structure according to an embodiment of the present application;

FIG. 5 is a schematic diagram of a structure of another pixel unit in a pixel arrangement structure according to an embodiment of the present application;

FIG. 6 is a schematic diagram of a structure of another pixel unit in a pixel arrangement structure according to an embodiment of the present application;

FIG. 7 is a schematic diagram of a structure of another pixel unit in a pixel arrangement structure according to an embodiment of the present application;

FIG. 8 is a schematic diagram of a structure of another pixel unit in a pixel arrangement structure according to an embodiment of the present application;

FIG. 9 is a schematic diagram of a structure of another pixel unit in a pixel arrangement structure according to an embodiment of the present application;

FIG. 10 is a schematic diagram of a structure of another pixel unit in a pixel arrangement structure according to an embodiment of the present application;

FIG. 11 is a schematic diagram of a structure of another pixel unit in a pixel arrangement structure according to an embodiment of the present application;

FIG. 12 is a schematic diagram of a structure of another pixel unit in a pixel arrangement structure according to an embodiment of the present application;

FIG. 13 is a schematic diagram of a structure of another pixel unit in a pixel arrangement structure according to an embodiment of the present application;

FIG. 14 is a schematic diagram of a structure of another pixel unit in a pixel arrangement structure according to an embodiment of the present application;

FIG. 15 is a schematic diagram of a structure of another pixel unit in a pixel arrangement structure according to an embodiment of the present application;

FIG. 16 is a schematic diagram of a structure of another pixel unit in a pixel arrangement structure according to an embodiment of the present application;

FIG. 17 is a schematic diagram of a structure of another pixel unit in a pixel arrangement structure according to an embodiment of the present application;

FIG. 18 is a schematic diagram of a structure of another pixel unit in a pixel arrangement structure according to an embodiment of the present application;

FIG. 19 is a schematic diagram of a structure of a display panel according to an embodiment of the present application;

FIG. 20 is a schematic partial enlarged view of a region Q in FIG. 19;

FIG. 21 is a schematic cross-sectional view of A-A in FIG. 20;

FIG. 22 is a schematic diagram of a structure of a mask in a mask assembly according to an embodiment of the present application; and

FIG. 23 is a schematic diagram of a structure of another mask in a mask assembly according to an embodiment of the present application.

### DETAILED DESCRIPTION OF EMBODIMENTS

The implementations of the present application are further described in detail below with reference to the accompanying drawings and embodiments. The following detailed description of the embodiments and the accompanying drawings are used to illustrate the principle of the present application in an exemplary manner, but shall not be used to limit the scope of the present application. That is, the present application is not limited to the described embodiments.

It should be noted that, herein, relative terms such as “first” and “second” are only used to distinguish one entity or operation from another entity or operation, and do not necessarily require or imply that such an actual relationship or order exists between these entities or operations. Moreover, the terms “include”, “comprise”, or any other variants thereof are intended to cover a non-exclusive inclusion, so that a process, a method, an article, or a device that includes a list of elements not only includes those elements but also includes other elements that are not listed, or further includes elements inherent to such a process, method, article, or device. If no more limitations are made, an element limited by “including a . . . ” does not exclude other identical elements existing in the process, the method, the article, or the device which includes the element.

With the advancement of science and technologies, people have increasingly high requirements for display panels, not only for the resolution of the display panels, but also for the display effect. A pixel arrangement plays a decisive role in the display quality of the display panels. Currently, a common pixel arrangement in the display panels is a regular matrix arrangement, which usually has low transmittance and is not conducive to wiring layout. Moreover, this arrangement manner further causes regular straight slits to be formed between metal electrodes corresponding to a pixel structure. When external light passes through the straight slits, severe diffraction occurs. The diffraction phenomenon increases display haze, resulting in deterioration in the display effect.

In order to solve the above problem, referring to FIG. 1 to FIG. 5, an embodiment of the present application provides a pixel arrangement structure, including a pixel unit 100. The pixel unit 100 includes a first pixel group 110, a second pixel group 120, and a third pixel group 130 arranged around a virtual center point O. The first pixel group 110 includes a plurality of first sub-pixels 111 arranged around a first virtual point O1, the second pixel group 120 includes a plurality of second sub-pixels 121 arranged around a second virtual point O2, and the third pixel group 130 includes a plurality of third sub-pixels 131 arranged around a third virtual point O3.

The plurality of first sub-pixels 111, as a pixel group, emit light of the same color, so that single-point color performance is good, and the display effect is better. Furthermore, this design is compatible with a color filter on encapsulation (COE) technology to further reduce a diffraction effect.

In the pixel unit 100, an orthographic projection of a first sub-pixel 111 located closest to the virtual center point O in a first direction X is located between projections of two second sub-pixels 121 in the first direction X. An orthographic projection of a second sub-pixel 121 located closest to the virtual center point O in a second direction Y is located between projections of two third sub-pixels 131 in the second direction Y. The first direction X intersects with the second direction Y.

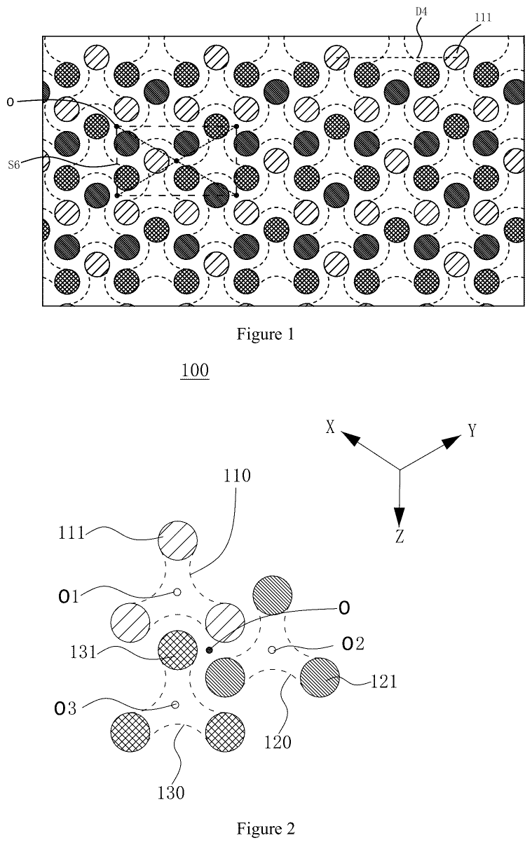

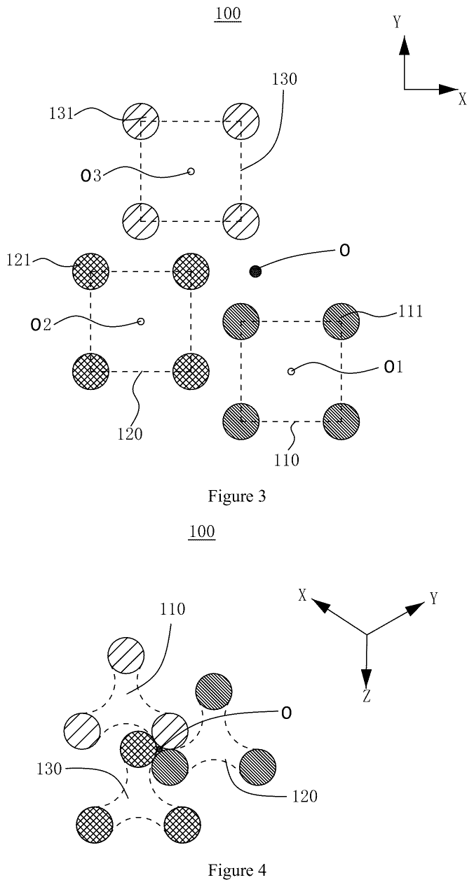

It should be noted that a relative position of a third sub-pixel 131 located closest to the virtual center point O is not limited in this embodiment of the present application. For example, as shown in FIG. 2, an orthographic projection of the third sub-pixel 131 located closest to the virtual center point O in a third direction Z may be located between projections of two first sub-pixels 111 in the third direction Z. In one embodiment, as shown in FIG. 3, an orthographic projection of the third sub-pixel 131 located closest to the virtual center point O in the second direction Y at least partially overlaps with an orthographic projection of the first sub-pixel 111 located closest to the virtual center point O.

The pixel arrangement structure includes sub-pixels of three different colors, i.e., the first sub-pixel 111, the second sub-pixel 121, and the third sub-pixel 131. In one embodiment, the first sub-pixel 111, the second sub-pixel 121, and the third sub-pixel 131 are respectively red, green, and blue sub-pixels.

The plurality of first sub-pixels 111 are arranged around the first virtual point O1 and combined to form the first pixel group 110. The first virtual point O1 mentioned in this embodiment of the present application means a geometric center of the first pixel group 110, i.e., the center of the first pixel group 110 coincides with the first virtual point O1. The plurality of first sub-pixels 111 may be spaced apart from each other and arranged around the first virtual point O1, or may abut against each other and be arranged around the first virtual point O1. In addition, the number of the first sub-pixels 111 in the first pixel group 110 is not limited in this embodiment of the present application. For example, as shown in FIG. 2 or FIG. 3, the first pixel group 110 may include three or four first sub-pixels 111.

The plurality of second sub-pixels 121 are arranged around the second virtual point O2 and combined to form the second pixel group 120. The second virtual point O2 mentioned in this embodiment of the present application means a geometric center of the second pixel group 120, i.e., the center of the second pixel group 120 coincides with the second virtual point O2. The plurality of second sub-pixels 121 may be spaced apart from each other and arranged around the second virtual point O2, or may abut against each other and be arranged around the second virtual point O2. In addition, the number of the second sub-pixels 121 in the second pixel group 120 is not limited in this embodiment of the present application. For example, as shown in FIG. 2 or FIG. 3, the second pixel group 120 may include three or four second sub-pixels 121.

The plurality of third sub-pixels 131 are arranged around the third virtual point O3 and combined to form the third pixel group 130. The third virtual point O3 mentioned in this embodiment of the present application means a geometric center of the third pixel group 130, i.e., the center of the third pixel group 130 coincides with the third virtual point O3. The plurality of third sub-pixels 131 may be spaced apart from each other and arranged around the third virtual point O3, or may abut against each other and be arranged around the third virtual point O3. In addition, the number of the third sub-pixels 131 in the third pixel group 130 is not limited in this embodiment of the present application. For example, as shown in FIG. 2 or FIG. 3, the third pixel group 130 may include three or four third sub-pixels 131.

The first pixel group 110, the second pixel group 120, and the third pixel group 130 jointly form the pixel unit 100. The pixel unit 100 is the smallest repeat unit in the pixel arrangement structure. A plurality of pixel units 100 are repeatedly translated to form the pixel arrangement structure. For example, the plurality of pixel units 100 may be repeatedly translated in a row direction and a column direction of a display panel to form the pixel arrangement structure.

In the single pixel unit 100, the first pixel group 110, the second pixel group 120, and the third pixel group 130 are arranged around a virtual center. The virtual center mentioned in this embodiment of the present application means a geometric center of the pixel unit 100, i.e., the center of the pixel unit 100 coincides with the virtual center point O. The first pixel group 110, the second pixel group 120, and the third pixel group 130 may be spaced apart from each other and arranged around the virtual center point O as shown in FIG. 2, or may abut against each other and be arranged around the virtual center point O as shown in FIG. 4. This is not limited in this embodiment of the present application.

In the single pixel unit 100, there is the first sub-pixel 111 located closest to the virtual center point O. The being located closest to the virtual center point O mentioned in this embodiment of the present application means that a distance between a center point of the first sub-pixel 111 and the virtual center point O is less than a distance between a center point of any other first sub-pixel 111 in the first pixel group 110 and the virtual center point O.

The projection of the first sub-pixel 111 in the first direction X is located between the projections of the two second sub-pixels 121 in the first direction X. The first direction X mentioned herein means a direction of a perpendicular line of a connection line of the centers of two second sub-pixels 121 in the second pixel group 120. Moreover, one of the two second sub-pixels 121 may be the second sub-pixel 121 located closest to the virtual center point O in the second pixel group 120. The two second sub-pixels 121 may alternatively be two second sub-pixels 121 located closest to the first sub-pixel 111 in the second pixel group 120.

Moreover, the “projection in the first direction X” mentioned in this embodiment of the present application means an orthographic projection on any plane perpendicular to the first direction X. Certainly, the projection in the second direction Y and the projection in the third direction Z are similar to the projection in the first direction X. Details are not described in this embodiment of the present application again.

In addition, in the single pixel unit 100, there is the second sub-pixel 121 located closest to the virtual center point O. The being located closest to the virtual center point O mentioned in this embodiment of the present application means a distance between a center point of the second sub-pixel 121 and the virtual center point O is less than a distance between a center point of any other second sub-pixel 121 in the second pixel group 120 and the virtual center point O.

The projection of the second sub-pixel 121 in the second direction Y is located between the projections of the two third sub-pixels 131 in the second direction Y. The second direction Y mentioned herein means a direction of a perpendicular line of a connection line of the centers of two third sub-pixels 131 in the third pixel group 130. Moreover, one of the two third sub-pixels 131 may be the third sub-pixel 131 located closest to the virtual center point O in the third pixel group 130. Specifically, the two third sub-pixels 131 may be two third sub-pixels 131 located closest to the second sub-pixel 121 in the third pixel group 130. The first direction X intersects with the second direction Y, and an included angle therebetween is not limited in this embodiment of the present application. For example, as shown in FIG. 3, the first direction X may be perpendicular to the second direction Y, or as shown in FIG. 2, an included angle between the first direction X and the second direction Y is 60°.

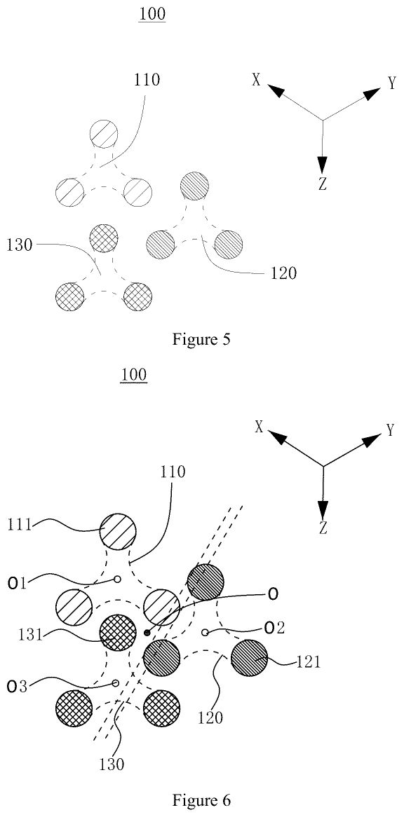

It should be noted that, as shown in FIG. 2, a partial structure in the first sub-pixel 111 located closest to the virtual center point O may be located on the same straight line as partial structures in the two second sub-pixels 121, i.e., the first sub-pixel 111 located closest to the virtual center point O is embedded between the two second sub-pixels 121, preferably at a middle position between the two second sub-pixels 121, and has equal distances to the two second sub-pixels 121. In one embodiment, as shown in FIG. 5, the first sub-pixel 111 located closest to the virtual center point O may be completely located outside a connection line of any partial structures in the two second sub-pixels 121. In one embodiment, the first sub-pixel 111 located closest to the virtual center point O has equal distances to the centers of the two second sub-pixels 121.

Similarly, a partial structure in the second sub-pixel 121 located closest to the virtual center point O may be located on the same straight line as partial structures in the two third sub-pixels 131, i.e., the second sub-pixel 121 located closest to the virtual center point O is embedded between the two third sub-pixels 131, preferably at a middle position between the two third sub-pixels 131, and has equal distances to the two third sub-pixels 131. In one embodiment, the second sub-pixel 121 located closest to the virtual center point O may be completely located outside a connection line of any partial structures in the two third sub-pixels 131. In one embodiment, the second sub-pixel 121 located closest to the virtual center point O has equal distances to the two third sub-pixels 131.

Similarly, a partial structure in the third sub-pixel 131 located closest to the virtual center point O may be located on the same straight line as partial structures in the two first sub-pixels 111, i.e., the third sub-pixel 131 located closest to the virtual center point O is embedded between the two first sub-pixels 111, preferably at a middle position between the two first sub-pixels 111, and has equal distances to the two first sub-pixels 111. In one embodiment, the third sub-pixel 131 located closest to the virtual center point O may be completely located outside a connection line of any partial structures in the two first sub-pixels 111. In one embodiment, the center of the third sub-pixel 131 located closest to the virtual center point O has equal distances to the centers of the two first sub-pixels 111.

In conclusion, in the single pixel unit 100 in this embodiment of the present application, in the first direction X, the projection of the first sub-pixel 111 is sandwiched between the projections of the two second sub-pixels 121. Moreover, in the second direction Y, the projection of the second sub-pixel 121 is sandwiched between the projections of the two third sub-pixels 131. Compared with a matrix pixel arrangement manner, this design may avoid formation of regular straight slits between electrodes corresponding to the pixel arrangement structure, thereby reducing a degree of diffraction and improving a display effect of a corresponding display panel.

In some embodiments, as shown in FIG. 2, FIG. 4, and FIG. 5, the projection of the third sub-pixel 131 located closest to the virtual center point O in the third direction Z is located between the projections of the two first sub-pixels 111 in the third direction Z, and the first direction X, the second direction Y, and the third direction Z intersect pairwise and are located in the same plane.

In the single pixel unit 100, there is the third sub-pixel 131 located closest to the virtual center point O. The being located closest to the virtual center point O mentioned in the embodiments of the present application means that a distance between a center point of the third sub-pixel 131 and the virtual center point O is less than a distance between a center point of any other third sub-pixel 131 in the third pixel group 130 and the virtual center point O.

Moreover, the projection of the third sub-pixel 131 in the third direction Z is located between the projections of the two first sub-pixels 111 in the first direction X. The third direction Z mentioned herein means a direction of a perpendicular line of a connection line of the centers of two first sub-pixels 111 in the first pixel group 110. Moreover, one of the two first sub-pixels 111 may be the first sub-pixel 111 located closest to the virtual center point O in the first pixel group 110.

It should be noted that a partial structure in the third sub-pixel 131 located closest to the virtual center point O may be located on the same straight line as partial structures in the two first sub-pixels 111, or the third sub-pixel 131 located closest to the virtual center point O may be completely outside a connection line of any partial structures in the two first sub-pixels 111. This is not limited in the embodiments of the present application.

The first direction X, the second direction Y, and the third direction Z intersect with each other and are all parallel to a light-emitting plane of the pixel arrangement structure. An included angle relationship among the first direction X, the second direction Y, and the third direction Z is not limited in the embodiments of the present application. For example, an included angle between any two of the first direction X, the second direction Y, and the third direction Z is 120°.

An orthographic projection of a sub-pixel in any one of the first pixel group 110, the second pixel group 120, and the third pixel group 130 is sandwiched between projections of two sub-pixels in another pixel group. Therefore, it can be learned with reference to the accompanying drawings that the first pixel group 110, the second pixel group 120, and the third pixel group 130 form a head-to-tail surrounding trend around the virtual center point O, the first virtual point O1 corresponding to the first pixel group 110, the second virtual point O2 corresponding to the second pixel group 120, and the third virtual point O3 corresponding to the third pixel group 130 are connected to form a triangular structure, and the virtual center point O is located inside the triangular structure.

In the embodiments of the present application, relative positions of the first pixel group 110, the second pixel group 120, and the third pixel group 130 are further improved by adjusting a position of the third pixel group 130, so that the three pixel groups can form a head-to-tail surrounding trend, thereby further increasing a difficulty of forming a straight-line region between adjacent pixel groups to alleviate a diffraction problem.

It should be noted that a relative position relationship between different pixel units is not limited in the embodiments of the present application. For example, as shown in FIG. 1, virtual center points O in four pixel groups may jointly form a second virtual quadrilateral S6, and an intersection point of two angle bisects of the second virtual quadrilateral S6 coincides with a virtual center point O in another pixel group. In addition, the second virtual quadrilateral S6 may be a square or a rectangular structure other than the square.

In some embodiments, as shown in FIG. 2, the projection of the first sub-pixel 111 located closest to the virtual center point O in the first direction X is located exactly in the middle of the projections of the two second sub-pixels 121 in the first direction X. That is, the center of the first sub-pixel 111 located closest to the virtual center point O has equal distances to the centers of the corresponding two second sub-pixels 121.

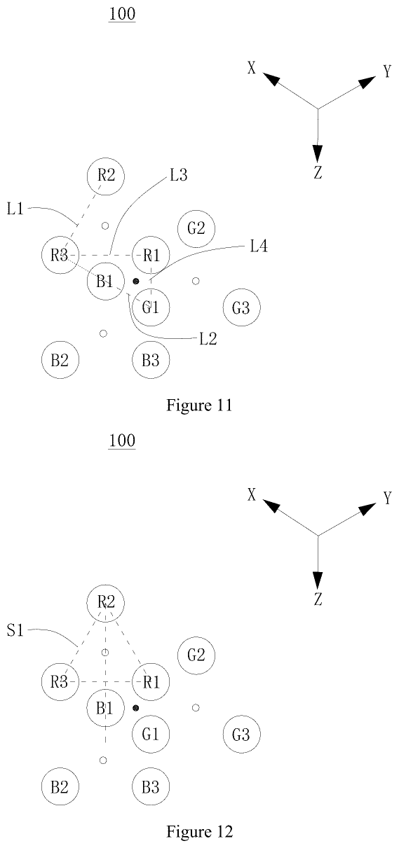

As shown in FIG. 8 and FIG. 11, in the embodiments of the present application, a position of the second pixel group 120 is determined through the first pixel group 110. Specifically, during a pixel arrangement process, a first virtual triangle S1 formed by three first sub-pixels 111 is first determined. A vertex of the first virtual triangle S1 and a point, i.e., two first sub-pixels 111 farther from the virtual center point O among the three first sub-pixels 111, are connected, such as a connection line L1 between R2 and R3 shown in FIG. 11, and then a perpendicular line L2 to L1 is drawn through R3. Then, for the vertex of the first virtual triangle S1, i.e., the first sub-pixel 111 farther from the virtual center point O, i.e., R2 in the figure, an angle bisector is drawn for an angle corresponding to R2 in the first virtual triangle S1. A point where the perpendicular line L2 intersects with the angle bisector is determined as a vertex of a third virtual triangle S3, i.e., a position of one of the third sub-pixels 131 is determined.

Similarly, the second sub-pixel 121 and the third sub-pixel 131 also conform to the above arrangement rule. Details are not described in this embodiment of the present application again.

In some embodiments, referring to FIG. 6, the first sub-pixel 111 located closest to the virtual center point O is at least partially embedded between two second sub-pixels 121. The “being embedded” mentioned in the embodiments of the present application means that, in the single pixel unit 100, a partial structure in the first sub-pixel 111 located closest to the virtual center point O and partial structures in the two second sub-pixels 121 are located on the same straight line. Two auxiliary dashed lines are provided in FIG. 6, and a part between the two auxiliary dashed lines is a partial structure that is in the first sub-pixel 111 located closest to the virtual center point O and that is embedded between the two second sub-pixels 121.

Because the first sub-pixel 111 located closest to the virtual center point O is at least partially embedded between the two second sub-pixels 121, there is no gap between the first sub-pixel 111 and the corresponding two second sub-pixels 121 in the first direction X. This design avoids formation of a regular rectangular gap space between the first pixel group 110 and the second pixel group 120, thereby reducing the degree of diffraction and improving the display effect.

In some embodiments, the second sub-pixel 121 located closest to the virtual center point O is at least partially embedded between two third sub-pixels 131. The “being embedded” mentioned in the embodiments of the present application means that, in the single pixel unit 100, a partial structure in the second sub-pixel 121 located closest to the virtual center point O and partial structures in the two third sub-pixels 131 are located on the same straight line.

Because the second sub-pixel 121 located closest to the virtual center point O is at least partially embedded between the two third sub-pixels 131, there is no gap between the second sub-pixel 121 and the corresponding two third sub-pixels 131 in the second direction Y. This design avoids formation of a regular rectangular gap space between the second pixel group 120 and the third pixel group 130, thereby reducing the degree of diffraction and improving the display effect.

In some embodiments, the third sub-pixel 131 located closest to the virtual center point O is at least partially embedded between two first sub-pixels 111. The “being embedded” mentioned in the embodiments of the present application means that, in the single pixel unit 100, a partial structure in the third sub-pixel 131 located closest to the virtual center point O and partial structures in the two first sub-pixels 111 are located on the same straight line.

Because the third sub-pixel 131 located closest to the virtual center point O is at least partially embedded between the two first sub-pixels 111, there is no gap between the third sub-pixel 131 and the corresponding two first sub-pixels 111 in the third direction Z. This design avoids formation of a regular rectangular gap space between the first pixel group 110 and the third pixel group 130, thereby reducing the degree of diffraction and improving the display effect.

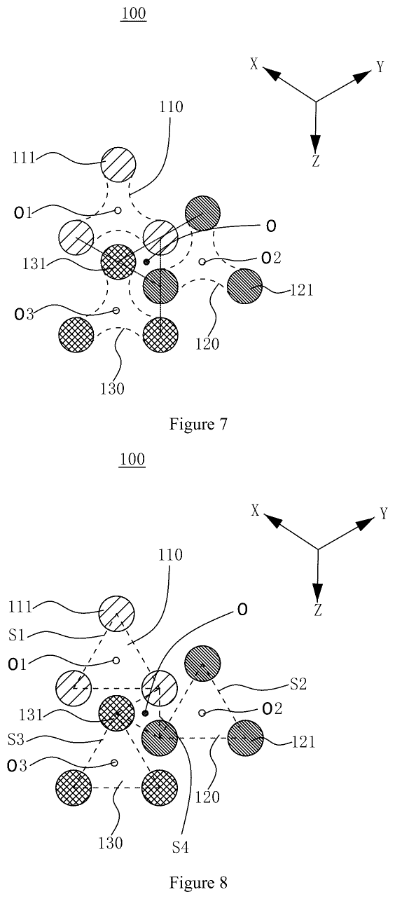

In some embodiments, referring to FIG. 7, the first sub-pixel 111 closest to the virtual center point O, the second sub-pixel 121 closest to the virtual center point O, and one third sub-pixel 131 in the third pixel group 130 are located on a straight line.

The “being on a straight line” mentioned in the embodiments of the present application means that connection lines of any two of the center point of the first sub-pixel 111 closest to the virtual center point O, the center point of the second sub-pixel 121 closest to the virtual center point O, and a center point of one third sub-pixel 131 in the third pixel group 130 are located on the same straight line. The third sub-pixel 131 is a third sub-pixel 131 located farther from the virtual center point O in the third pixel group 130.

The second sub-pixel 121 located closest to the virtual center point O is sandwiched between the first sub-pixel 111 located closest to the virtual center point O and one third sub-pixel 131 in the third pixel group 130. Among the three sub-pixels, a distance between the centers of the second sub-pixel 121 and the first sub-pixel 111 may be the same as or different from a distance between the centers of the second sub-pixel 121 and the third sub-pixel 131. In addition, an extension direction of the straight line on which the three sub-pixels are located may be parallel to the third direction Z, or may have a specific inclination angle with respect to the third direction Z. This is not limited in the embodiments of the present application.

In some other embodiments, as shown in FIG. 7, the second sub-pixel 121 closest to the virtual center point O, the third sub-pixel 131 closest to the virtual center point O, and one first sub-pixel 111 in the first pixel group 110 are located on a straight line.

The “being on a straight line” mentioned in the embodiments of the present application means that connection lines of any two of the center point of the second sub-pixel 121 closest to the virtual center point O, the center point of the third sub-pixel 131 closest to the virtual center point O, and a center point of one first sub-pixel 111 in the first pixel group 110 are located on the same straight line. The first sub-pixel 111 is a first sub-pixel 111 located farther from the virtual center point O in the first pixel group 110.

The third sub-pixel 131 located closest to the virtual center point O is sandwiched between the second sub-pixel 121 located closest to the virtual center point O and one first sub-pixel 111 in the first pixel group 110. Among the three sub-pixels, a distance between the centers of the third sub-pixel 131 and the first sub-pixel 111 may be the same as or different from a distance between the centers of the third sub-pixel 131 and the second sub-pixel 121. In addition, an extension direction of the straight line on which the three sub-pixels are located may be parallel to the first direction X, or may have a specific inclination angle with respect to the first direction X. This is not limited in the embodiments of the present application.

In some other embodiments, as shown in FIG. 7, the third sub-pixel 131 closest to the virtual center point O, the first sub-pixel 111 closest to the virtual center point O, and one second sub-pixel 121 in the second pixel group 120 are located on a straight line.

The “being on a straight line” mentioned in the embodiments of the present application means that connection lines of any two of the center point of the third sub-pixel 131 closest to the virtual center point O, the center point of the first sub-pixel 111 closest to the virtual center point O, and a center point of one second sub-pixel 121 in the second pixel group 120 are located on the same straight line. The third sub-pixel 131 is a third sub-pixel 131 located farther from the virtual center point O in the third pixel group 130.

The second sub-pixel 121 located closest to the virtual center point O is sandwiched between the first sub-pixel 111 located closest to the virtual center point O and one third sub-pixel 131 in the third pixel group 130. Among the three sub-pixels, a distance between the centers of the first sub-pixel 111 and the second sub-pixel 121 may be the same as or different from a distance between the centers of the first sub-pixel 111 and the third sub-pixel 131. In addition, an extension direction of the straight line on which the three sub-pixels are located may be parallel to the second direction Y, or may have a specific inclination angle with respect to the second direction Y. This is not limited in the embodiments of the present application.

In the above embodiments, the first sub-pixel 111, the second sub-pixel 121, and the third sub-pixel 131 in the pixel unit 100 can be located on the same straight line by adjusting positions of some of the first sub-pixels 111, the second sub-pixels 121, and the third sub-pixels 131, thereby achieving regular arrangement of some of the first sub-pixels 111, some of the second sub-pixels 121, and some of the third sub-pixels 131 while reducing diffraction, and improving display uniformity.

In some embodiments, referring to FIG. 8, the first pixel group 110 includes three first sub-pixels 111, and the three first sub-pixels 111 are connected to form the first virtual triangle S1.

The first pixel group 110 includes three first sub-pixels 111. Connection lines of the centers of the three first sub-pixels 111 jointly form the first virtual triangle S1. The first virtual point O1 is located inside the first virtual triangle S1. A specific size and shape of the first virtual triangle S1 are not limited in the embodiments of the present application, and distances between the first virtual point O1 and three endpoints of the first virtual triangle S1 may be the same or different.

In the embodiments of the present application, the number of the first sub-pixels 111 in the first pixel group 110 is set to three, and then relative positions of the plurality of first sub-pixels 111 are determined by adjusting positions of the endpoints of the first virtual triangle S1. Compared with a solution in which a larger number of first sub-pixels 111 are provided, in the embodiments of the present application, a spacing between adjacent first sub-pixels 111 can be increased, thereby reducing a difficulty of vapor deposition of the first sub-pixels 111 during production of the display panel.

In some other embodiments, as shown in FIG. 8, the second pixel group 120 includes three second sub-pixels 121, and the three second sub-pixels 121 are connected to form a second virtual triangle S2.

The second pixel group 120 includes three second sub-pixels 121. Connection lines of the centers of the three second sub-pixels 121 jointly form the second virtual triangle S2. The second virtual point O2 is located inside the second virtual triangle S2. A specific size and shape of the second virtual triangle S2 are not limited in the embodiments of the present application, and distances between the second virtual point O2 and three endpoints of the second virtual triangle S2 may be the same or different.

In the embodiments of the present application, the number of the second sub-pixels 121 in the second pixel group 120 is set to three, and then relative positions of the plurality of second sub-pixels 121 are determined by adjusting positions of the endpoints of the second virtual triangle S2. Compared with a solution in which a larger number of second sub-pixels 121 are provided, in the embodiments of the present application, a spacing between adjacent second sub-pixels 121 can be increased, thereby reducing a difficulty of vapor deposition of the second sub-pixels 121 during production of the display panel.

In some other embodiments, as shown in FIG. 8, the third pixel group 130 includes three third sub-pixels 131, and the three third sub-pixels 131 are connected to form the third virtual triangle S3.

The third pixel group 130 includes three third sub-pixels 131. Connection lines of the centers of the three third sub-pixels 131 jointly form the third virtual triangle S3. The third virtual point O3 is located inside the third virtual triangle S3 in the display panel. A specific size and shape of the third virtual triangle S3 are not limited in the embodiments of the present application, and distances between the third virtual point O3 and three endpoints of the third virtual triangle S3 may be the same or different.

In the embodiments of the present application, the number of the third sub-pixels 131 in the third pixel group 130 is set to three, and then relative positions of the plurality of third sub-pixels 131 are determined by adjusting positions of the endpoints of the third virtual triangle S3. Compared with a solution in which a larger number of third sub-pixels 131 are provided, in the embodiments of the present application, a spacing between adjacent third sub-pixels 131 can be increased, thereby reducing a difficulty of vapor deposition of the third sub-pixels 131 during production of the display panel.

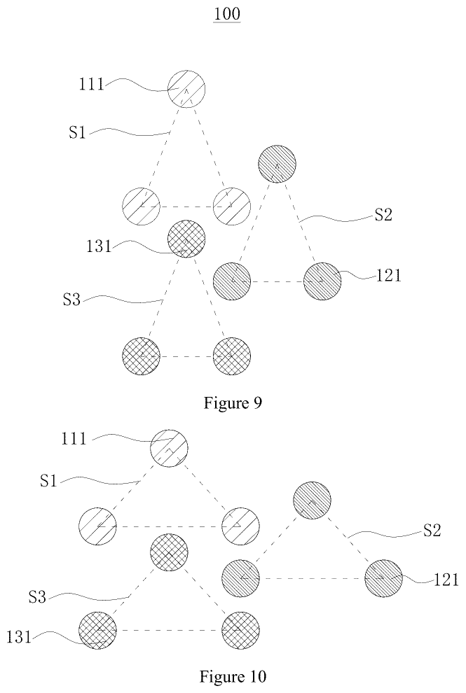

In some embodiments, referring to FIG. 9 and FIG. 10, the first virtual triangle S1 is an isosceles triangle. The first virtual triangle S1 may be a longitudinal isosceles triangle shown in FIG. 9 or a transverse isosceles triangle shown in FIG. 10.

In the embodiments of the present application, the first virtual triangle S1 is an isosceles triangle, which indicates that lengths of connection lines of the center of at least one first sub-pixel 111 in the first pixel group 110 and the centers of the other two first sub-pixels 111 in the first pixel group 110 are the same. This design enables the three first sub-pixels 111 in the first pixel group 110 to be arranged in a specific pattern, thereby improving the display effect while reducing diffraction. In one embodiment, at least one of the second virtual triangle S2 and the third virtual triangle S3 is also an isosceles triangle.

In some embodiments, as shown in FIG. 8, the first virtual triangle S1 is an equilateral triangle.

In the embodiments of the present application, the first virtual triangle S1 is an equilateral triangle, which indicates that lengths of connection lines of the center of any first sub-pixel 111 in the first pixel group 110 and the centers of the other two first sub-pixels 111 in the first pixel group 110 are the same. This design can further improve the uniformity of arrangement of the first sub-pixels 111 in the first pixel group 110, thereby improving the display effect. A side length of the first virtual triangle S1 is not limited in the embodiments of the present application.

In some embodiments, at least one of the second virtual triangle S2 and the third virtual triangle S3 is also an equilateral triangle.

In some embodiments, as shown in FIG. 8, at least two of the first sub-pixel 111, the second sub-pixel 121, and the third sub-pixel 131 that are located closest to the virtual center point O have equal distances to the virtual center point O.

In the first pixel group 110, different first sub-pixels 111 have different distances to the virtual center point O, and therefore there is the first sub-pixel 111 located closest to the virtual center point O. In the second pixel group 120, different second sub-pixels 121 have different distances to the virtual center point O, and therefore there is the second sub-pixel 121 located closest to the virtual center point O. In the third pixel group 130, different third sub-pixels 131 have different distances to the virtual center point O, and therefore there is the third sub-pixel 131 located closest to the virtual center point O. Moreover, three sub-pixels of different colors that are closest to the virtual center point O can jointly form a light-emitting unit, thereby meeting an actual light-emitting requirement.

Based on this, in the embodiments of the present application, the distances between at least two of the first sub-pixel 111, the second sub-pixel 121, and the third sub-pixel 131 that are located closest to the virtual center point O and the virtual center point O are set to be equal, i.e., lengths of connection lines of corresponding centers of at least two sub-pixels among these three sub-pixels and the virtual center point O are the same. For example, the distance between the first sub-pixel 111 located closest to the virtual center point O and the virtual center point O is equal to the distance between the second sub-pixel 121 located closest to the virtual center point O and the virtual center point O.

This design makes a light-emitting center of the light-emitting unit formed by the three sub-pixels of different colors that are closest to the virtual center point O as close as possible to the virtual center point O, i.e., the light-emitting center is located as close as possible to a central position of the entire pixel unit 100, thereby improving the display uniformity.

In some embodiments, the first sub-pixel 111, the second sub-pixel 121, and the third sub-pixel 131 that are located closest to the virtual center point O have equal distances to the virtual center point O.

In the embodiments of the present application, the distance between the first sub-pixel 111 located closest to the virtual center point O and the virtual center point O, the distance between the second sub-pixel 121 located closest to the virtual center point O and the virtual center point O, and the distance between the third sub-pixel 131 located closest to the virtual center point O and the virtual center point O are all the same. Therefore, the light-emitting center of the light-emitting unit formed by the three sub-pixels of different colors that are closest to the virtual center point O corresponds to the virtual center point O, i.e., the light-emitting center is located exactly at a central position of the entire pixel unit 100, thereby achieving unity of a physical structure and a display effect, and further improving the display uniformity.

In some embodiments, as shown in FIG. 8, the first sub-pixel 111, the second sub-pixel 121, and the third sub-pixel 131 that are located closest to the virtual center point O are connected to form a fourth virtual triangle S4, and the fourth virtual triangle S4 is an equilateral triangle.

Connection lines of the centers the three sub-pixels of different colors that are located closest to the virtual center point O form the fourth virtual triangle S4. Three endpoints of the fourth virtual triangle S4 are the center of the first sub-pixel 111, the center of the second sub-pixel 121, and the center of the third sub-pixel 131. The virtual center point O is located inside the fourth virtual triangle S4.

The fourth virtual triangle S4 is an equilateral triangle, which indicates that distances between any two of the first sub-pixel 111, the second sub-pixel 121, and the third sub-pixel 131 that are located closest to the virtual center point O are equal. Moreover, the three sub-pixels have equal distances to the virtual center point O. This design can further achieve regular arrangement of sub-pixels while reducing diffraction, thereby ensuring the reliable and stable display effect.

In some embodiments, the first virtual triangle S1 includes a first virtual side L1 connecting two first sub-pixels 111 located farther from the virtual center point O, the fourth virtual triangle S4 includes a second virtual side L2 connecting the second sub-pixel 121 and the third sub-pixel 131 that are located closest to the virtual center point O, and the first virtual side L1 and the second virtual side L2 perpendicularly intersect at one first sub-pixel 111 located farther from the virtual center point O.

It can be learned from the above content that the first sub-pixel 111, the second sub-pixel 121, and the third sub-pixel 131 are sub-pixels of different colors. Based on this, in order to facilitate subsequent description of the pixel arrangement structure, subsequent embodiments of the present application will be described with reference to FIG. 8 and FIG. 11 by using an example in which the first sub-pixel 111 is a red sub-pixel, the second sub-pixel 121 is a green sub-pixel, and the third sub-pixel 131 is a blue sub-pixel. The plurality of first sub-pixels 111 include a first red sub-pixel R1, a second red sub-pixel R2, and a third red sub-pixel R3. The plurality of second sub-pixels 121 include a first green sub-pixel G1, a second green sub-pixel G2, and a third green sub-pixel G3. The plurality of third sub-pixels 131 include a first blue sub-pixel B1, a second blue sub-pixel B2, and a third blue sub-pixel B3. The first red sub-pixel R1, the first green sub-pixel G1, and the first blue sub-pixel B1 are sub-pixels of different colors that are located closest to the virtual center point O.

Two endpoints of the first virtual side L1 are respectively the centers of the second red sub-pixel R2 and the third red sub-pixel R3, and two endpoints of the second virtual side L2 are respectively the centers of the first green sub-pixel G1 and the first blue sub-pixel B1. An extension line of the second virtual side L2 intersects with the first virtual side L1 in the third red sub-pixel R3, i.e., center points of the third red sub-pixel R3, the first blue sub-pixel B1, and the first green sub-pixel G1 are located on the same straight line.

Based on this, in the embodiments of the present application, the first virtual side L1 is set perpendicular to the second virtual side L2, thereby further limiting a relationship between sub-pixels of different colors in the pixel unit 100. This allows the sub-pixels to be arranged more regularly, improving the display uniformity.

In some embodiments, referring to FIG. 8 and FIG. 11, the first virtual triangle S1 includes a third virtual side L3 connecting the first sub-pixel 111 located closest to the virtual center point O and the first sub-pixel 111 located farther from the virtual center point O, and the fourth virtual triangle S4 includes a fourth virtual side L4 connecting the first sub-pixel 111 and the second sub-pixel 121 that are located closest to the virtual center point O, and the third virtual side L3 is perpendicular to the fourth virtual side L4.

Two endpoints of the third virtual side L3 are respectively the centers of the first red sub-pixel R1 and the third red sub-pixel R3, and two endpoints of the fourth virtual side L4 are respectively the centers of the first red sub-pixel R1 and the first green sub-pixel G1. The third virtual side L3 and the fourth virtual side L4 perpendicularly intersect at the first red sub-pixel R1, i.e., an included angle between a connection line of the first green sub-pixel G1 and the first red sub-pixel R1 and a connection line of the third red sub-pixel R3 and the first red sub-pixel R1 is 90°.

It can be learned from the above content that the first virtual triangle S1 is an equilateral triangle. Therefore, included angles of the first virtual triangle S1 at the three endpoints are all 60°, that is, an included angle of the first virtual triangle S1 at the third red sub-pixel R3 is 60°. Based on this, because the first virtual side L1 and the second virtual side L2 are perpendicular to each other, an included angle between a connection line of the first green sub-pixel G1 and the third red sub-pixel R3 and a connection line of the second red sub-pixel R2 and the third red sub-pixel R3 is 90°. It can thus be deduced that an included angle between the connection line of the first green sub-pixel G1 and the third red sub-pixel R3 and the connection line of the first red sub-pixel R1 and the third red sub-pixel R3 is 30°.

In conclusion, the included angle between the connection line of the first green sub-pixel G1 and the first red sub-pixel R1 and the connection line of the third red sub-pixel R3 and the first red sub-pixel R1 is 90°, and the included angle between the connection line of the first green sub-pixel G1 and the third red sub-pixel R3 and the connection line of the first red sub-pixel R1 and the third red sub-pixel R3 is 30°. Therefore, a fifth virtual triangle formed by connection lines of the centers of the first red sub-pixel R1, the first green sub-pixel G1, and the third red sub-pixel R3 is a right triangle with an included angle of 30°. Therefore, a relationship among a connection line distance between the first green sub-pixel G1 and the third red sub-pixel R3, a connection line distance between the first green sub-pixel G1 and the first red sub-pixel R1, and a connection line distance between the first red sub-pixel R1 and the third red sub-pixel R3 is 2:1:√3.

In some embodiments, the first virtual triangle S1 and the fourth virtual triangle S4 may both be equilateral triangles, and the connection line distance between the first red sub-pixel R1 and the third red sub-pixel R3 is a side length M of the first virtual triangle S1, and the connection line distance between the first green sub-pixel G1 and the third red sub-pixel R3 is a side length N of the fourth virtual triangle S4. Therefore, in some embodiments, M and N satisfy: M=N*√3.

It should be noted that, for the second virtual triangle S2, a side length relationship between the second virtual triangle S2 and the fourth virtual triangle S4 may be the same as a side length relationship between the first virtual triangle S1 and the fourth virtual triangle S4. Similarly, for the third virtual triangle S3, a side length relationship between the third virtual triangle S3 and the fourth virtual triangle S4 may be the same as the side length relationship between the first virtual triangle S1 and the fourth virtual triangle S4. This is not limited in the embodiments of the present application.

In addition, because the fourth virtual triangle S4 may be an equilateral triangle, a connection line distance between the center of the first blue sub-pixel B1 and the center of the first green sub-pixel G1 may be equal to a connection line distance between the center of the first green sub-pixel G1 and the center of the first red sub-pixel R1. Because a connection line distance between the center of the first green sub-pixel G1 and the center of the third red sub-pixel R3 may be twice the connection line distance between the center of the first red sub-pixel R1 and the center of the first green sub-pixel G1, the connection line distance between the center of the first blue sub-pixel B1 and the center of the first green sub-pixel G1 may be equal to a connection line distance between the center of the first blue sub-pixel B1 and the center of the third red sub-pixel R3, i.e., the center of the first blue sub-pixel B1 may be located at a central position between the center of the first green sub-pixel G1 and the center of the third red sub-pixel R3.

Referring to FIG. 1 and FIG. 8, a fourth virtual connection line D2 is used to connect the centers of two adjacent first sub-pixels 111 in the same row. In other words, a length of the fourth virtual connection line D2 is a spacing between two adjacent pixel groups 100 in the same row. In some embodiments, the length of the fourth virtual connection line D2 may be 2M, i.e., twice the side length of the first virtual triangle S1.

In some embodiments, referring to FIG. 8 and FIG. 12, the third sub-pixel 131 located closest to the virtual center point O is located on an angle bisector of an angle of the first virtual triangle S1.

The first blue sub-pixel B1 is located on an angle bisector of an included angle that is formed by a connection line of the centers of the first red sub-pixel R1 and the second red sub-pixel R2 and a connection line of the centers of the second red sub-pixel R2 and the third red sub-pixel R3. Because the first virtual triangle S1 is an equilateral triangle, the first blue sub-pixel B1 being located on the angle bisector means that a connection line distance between the centers of the first blue sub-pixel B1 and the first red sub-pixel R1 is the same as a connection line distance between the centers of the first blue sub-pixel B1 and the third red sub-pixel R3.

In some embodiments, the first red sub-pixel R1 is located on an angle bisector of an included angle that is formed by a connection line of the centers of the first green sub-pixel G1 and the third green sub-pixel G3 and a connection line of the centers of the second green sub-pixel G2 and the third green sub-pixel G3, i.e., on an angle bisector of the second virtual triangle S2. The first green sub-pixel G1 is located on an angle bisector of an included angle that is formed by a connection line of the centers of the first blue sub-pixel B1 and the second blue sub-pixel B2 and a connection line of the centers of the second blue sub-pixel B2 and the third blue sub-pixel B3, i.e., on an angle bisector of the third virtual triangle S3.

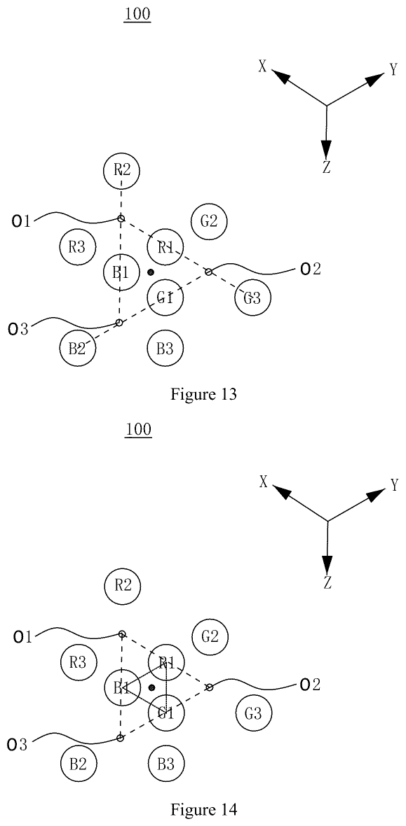

In some embodiments, referring to FIG. 8 and FIG. 13, a first sub-pixel 111 is arranged on a virtual connection line of the first virtual point O1 and the second virtual point O2.

The first red sub-pixel R1 may be located on the virtual connection line of the first virtual point O1 and the second virtual point O2, where a connection line distance between the centers of the first virtual point O1 and the first red sub-pixel R1 may be greater than a connection line distance between the centers of the second virtual point O2 and the first red sub-pixel R1, or may be less than or equal to the connection line distance between the centers of the second virtual point O2 and the first red sub-pixel R1. This is not limited in the embodiments of the present application.

Similarly, in some embodiments, a second sub-pixel 121 is arranged on a virtual connection line of the second virtual point O2 and the third virtual point O3.

The first green sub-pixel G1 may be located on the virtual connection line of the second virtual point O2 and the third virtual point O3, where a connection line distance between the centers of the second virtual point O2 and the first green sub-pixel G1 may be greater than a connection line distance between the centers of the third virtual point O3 and the first green sub-pixel G1, or may be less than or equal to the connection line distance between the centers of the third virtual point O3 and the first green sub-pixel G1. This is not limited in the embodiments of the present application.

Similarly, in some embodiments, a third sub-pixel 131 is arranged on a virtual connection line of the first virtual point O1 and the third virtual point O3.

The first blue sub-pixel B1 may be located on the virtual connection line of the first virtual point O1 and the third virtual point O3, where a connection line distance between the centers of the first virtual point O1 and the first blue sub-pixel B1 may be greater than a connection line distance between the centers of the third virtual point O3 and the first blue sub-pixel B1, or may be less than or equal to the connection line distance between the centers of the third virtual point O3 and the first blue sub-pixel B1. This is not limited in the embodiments of the present application.

In some embodiments, as shown in FIG. 8 and FIG. 13, a second sub-pixel 121 is arranged on an extension line of the connection line of the first virtual point O1 and the second virtual point O2, and the second sub-pixel 121 is located on a side that is of the second virtual point O2 and that is away from the first virtual point O1.

The center of the third green sub-pixel G3 may be located on the extension line of the virtual connection line of the first virtual point O1 and the second virtual point O2. Further, the first virtual point O1, the center of the first red sub-pixel R1, the second virtual point O2, and the center of the third green sub-pixel G3 are all located on the same straight line, so that the pixel arrangement structure can be further optimized to make the arrangement thereof more regular, improving the display effect.

In some embodiments, a third sub-pixel 131 is arranged on an extension line of the connection line of the second virtual point O2 and the third virtual point O3, and the third sub-pixel 131 is located on a side that is of the third virtual point O3 and that is away from the second virtual point O2.

The center of the second blue sub-pixel B2 may be located on the extension line of the virtual connection line of the second virtual point O2 and the third virtual point O3. Further, the second virtual point O2, the center of the first green sub-pixel G1, the third virtual point O3, and the center of the second blue sub-pixel B2 are all located on the same straight line, so that the pixel arrangement structure can be further optimized to make the arrangement thereof more regular, improving the display effect.

In some embodiments, a first sub-pixel 111 is arranged on an extension line of the connection line of the first virtual point O1 and the third virtual point O3, and the first sub-pixel 111 is located on a side that is of the first virtual point O1 and that is away from the third virtual point O3.

The center of the second red sub-pixel R2 may be located on the extension line of the virtual connection line of the first virtual point O1 and the third virtual point O3. Further, the third virtual point O3, the center of the first blue sub-pixel B1, the first virtual point O1, and the center of the second red sub-pixel R2 are all located on the same straight line, so that the pixel arrangement structure can be further optimized to make the arrangement thereof more regular, improving the display effect.

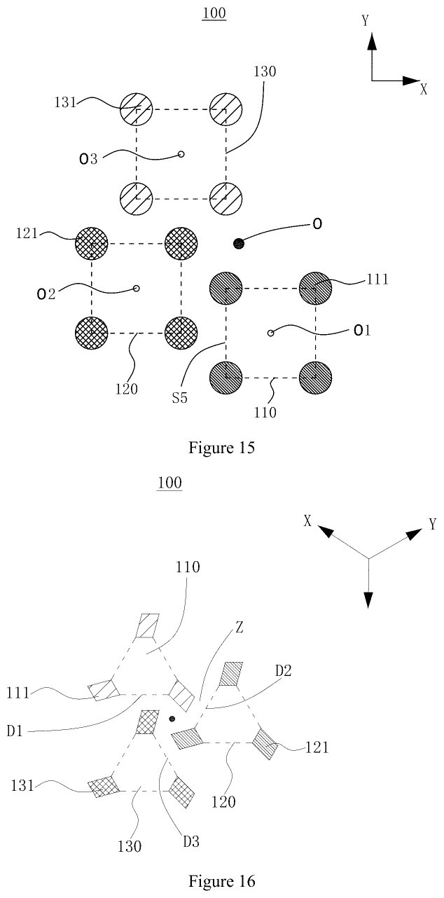

In some embodiments, referring to FIG. 8 and FIG. 14, the direction of the connection line of the first sub-pixel 111 located closest to the virtual center point O and the second sub-pixel 121 located closest to the virtual center point O is parallel to the direction of the connection line of the first virtual point O1 and the third virtual point O3.

An extension direction of the connection line of the centers of the first red sub-pixel R1 and the first green sub-pixel G1 is parallel to an extension direction of the connection line of the first virtual point O1 and the third virtual point O3. The third direction Z may be parallel to the extension direction of the connection line of the first virtual point O1 and the third virtual point O3. Therefore, the extension direction of the connection line of the centers of the first red sub-pixel R1 and the first green sub-pixel G1 may also be parallel to the third direction Z.

In some embodiments, as shown in FIG. 8 and FIG. 14, the direction of the connection line of the second sub-pixel 121 located closest to the virtual center point O and the third sub-pixel 131 located closest to the virtual center point O is parallel to the direction of the connection line of the first virtual point O1 and the second virtual point O2.

An extension direction of the connection line of the centers of the first green sub-pixel G1 and the first blue sub-pixel B1 is parallel to an extension direction of the connection line of the first virtual point O1 and the second virtual point O2. The first direction X may be parallel to the extension direction of the connection line of the first virtual point O1 and the second virtual point O2. Therefore, the extension direction of the connection line of the centers of the first green sub-pixel G1 and the first blue sub-pixel B1 may also be parallel to the first direction X.

In some embodiments, as shown in FIG. 8 and FIG. 14, the direction of the connection line of the first sub-pixel 111 located closest to the virtual center point O and the third sub-pixel 131 located closest to the virtual center point O is parallel to the direction of the connection line of the second virtual point O2 and the third virtual point O3.

An extension direction of the connection line of the centers of the first red sub-pixel R1 and the first blue sub-pixel B1 is parallel to an extension direction of the connection line of the second virtual point O2 and the third virtual point O3. The second direction Y may be parallel to the extension direction of the connection line of the second virtual point O2 and the third virtual point O3. Therefore, the extension direction of the connection line of the centers of the first red sub-pixel R1 and the first blue sub-pixel B1 may also be parallel to the second direction Y.

In some embodiments, referring to FIG. 15, the first pixel group 110 includes four first sub-pixels 111, and the four first sub-pixels 111 are connected to form a first virtual quadrilateral S5.

In the embodiments of the present application, the first pixel group 110 may include four first sub-pixels 111. Similarly, for example, the second pixel group 120 may include four second sub-pixels 121, and the third pixel group 130 may include four third sub-pixels 131. Connection lines of the centers of the four first sub-pixels 111 form the first virtual quadrilateral S5, and the first virtual point O1 is located inside the first virtual quadrilateral S5. The first virtual point O1 may be located exactly at the center of the first virtual quadrilateral S5, i.e., distances between the centers of the first sub-pixels 111 and the first virtual point O1 are all the same.

The number of first sub-pixels 111 in the first pixel group 110 is increased to four, so that luminous brightness of a color corresponding to the first sub-pixel 111 can be increased to some extent, and a maximum brightness difference between the first sub-pixel and sub-pixels of other colors can be increased, thereby improving display contrast.

In some embodiments, the first virtual quadrilateral S5 is a parallelogram.

In the embodiments of the present application, both a length and an extension direction of a connection line of any two first sub-pixels 111 in the first pixel group 110 are the same as a length and an extension direction of a connection line of the other two first sub-pixels 111, thereby optimizing an arrangement manner of the plurality of first sub-pixels 111 in the first pixel group 110, and improving a corresponding display effect. Similarly, for example, the centers of the four second sub-pixels 121 in the second pixel group 120 may be connected to form a parallelogram, and the centers of the four third sub-pixels 131 in the third pixel group 130 may also be connected to form a parallelogram.

In some embodiments, the first virtual quadrilateral S5 is a rectangle.

In the embodiments of the present application, any two adjacent sides of the first virtual quadrilateral S5 are set perpendicular to each other, so that the plurality of first sub-pixels 111 in the first pixel group 110 are arranged more regularly. Similarly, for example, the centers of the four second sub-pixels 121 in the second pixel group 120 may alternatively be connected to form a rectangle, and the centers of the four third sub-pixels 131 in the third pixel group 130 may also be connected to form a rectangle.

In some embodiments, as shown in FIG. 5, the first virtual quadrilateral S5 is a square.

In the embodiments of the present application, any two adjacent sides of the first virtual quadrilateral S5 are perpendicular to each other and have the same length, so that the plurality of first sub-pixels 111 in the first pixel group 110 are arranged more regularly. Similarly, for example, the centers of the four second sub-pixels 121 in the second pixel group 120 may alternatively be connected to form a square, and the centers of the four third sub-pixels 131 in the third pixel group 130 may also be connected to form a square.

In some embodiments, referring to FIG. 16, the first pixel group 110, the second pixel group 120, and the third pixel group 130 are arranged separately to form a wiring region Z among them.

The first pixel group 110 and the second pixel group 120 are used as an example. The first pixel group 110 and the second pixel group 120 being arranged separately means that there is a gap between the first pixel group 110 and the second pixel group 120, and there are no other sub-pixels in the gap. Gaps formed by the first pixel group 110, the second pixel group 120, and the third pixel group 130 jointly form the wiring region Z.

In a corresponding display panel using the pixel arrangement structure in the embodiments of the present application, a wiring structure may be arranged in the corresponding wiring region Z, to conduct a pixel circuit and meet a display requirement. It can be learned from the above content that the projection of the first sub-pixel 111 located closest to the virtual center point O in the first direction X is located between the projections of the two second sub-pixels 121 in the first direction X, and the projection of the second sub-pixel 121 located closest to the virtual center point O in the second direction Y is located between the projections of the two third sub-pixels 131 in the second direction Y. Therefore, a shape of the wiring region Z is unlikely to be a regular rectangular structure, thereby reducing the degree of diffraction. That is, in the embodiments of the present application, the display effect can be further improved while a wiring requirement is met.

In some embodiments, as shown in FIG. 16, the second pixel group includes a second virtual connection line D2 connecting two second sub-pixels 121, and the first sub-pixel 111 located closest to the virtual center point O is spaced apart from the second virtual connection line D2 to form a part of the wiring region Z between the first sub-pixel 111 and the second virtual connection line.

Two ends of the second virtual connection line D2 are respectively connected to peripheries of the two second sub-pixels 121. The second virtual connection line D2 and the first sub-pixel 111 are spaced apart, and jointly form a part of the wiring region Z. Moreover, a shape of the second virtual connection line D2 and a shape of the first sub-pixel 111 can jointly define a shape of a partial structure in the wiring region Z. For example, if the shape of the first sub-pixel 111 is a polygon, and the second virtual connection line D2 is a straight-line structure, a corresponding wiring region Z formed by them is a zigzag channel. Certainly, if the first sub-pixel 111, the second sub-pixel 121, and the third sub-pixel 131 are circular, and a first virtual connection line D1, the second virtual connection line D2, and a third virtual connection line D3 are straight lines, a wiring region Z may also be implemented. In this case, the wiring region Z is also approximately a zigzag channel. In the corresponding display panel, wires extend in a zigzag shape. Compared with a solution in which a wiring region Z is a straight channel, this design may reduce the degree of diffraction and improve the display effect.

It should be noted that the first pixel group may also include the first virtual connection line D1 connecting peripheries of two first sub-pixels 111, and the first virtual connection line D1 may be spaced apart from the third sub-pixel 131 to form at least part of the wiring region Z. The third pixel group may also include the third virtual connection line D3 connecting peripheries of two third sub-pixels 131, and the third virtual connection line D3 may be spaced apart from the second sub-pixel 121 to form a part of the wiring region Z. The first virtual connection line D1, the second virtual connection line D2, and the third virtual connection line D3 may have similar or identical shapes, or may have completely different shapes. This is not limited in the embodiments of the present application.

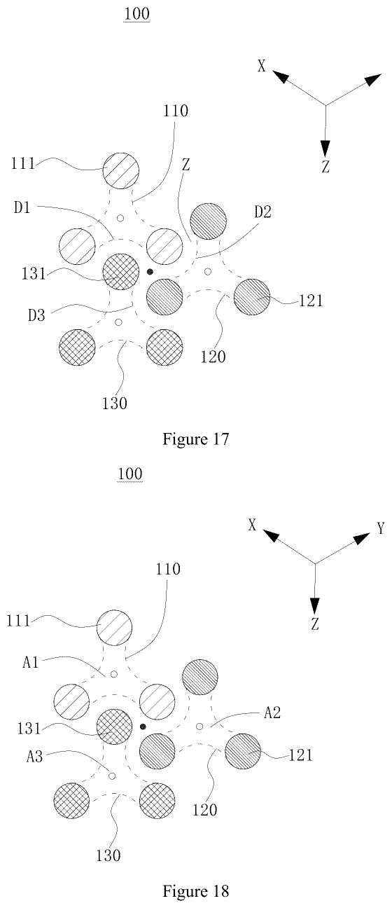

In some embodiments, referring to FIG. 17, the second virtual connection line D2 includes an arc-shaped segment.

Because the second virtual connection line D2 includes the arc-shaped segment, a corresponding part of an outer contour in the wiring region Z is an arc shape. In the corresponding display panel, some wires may be arranged to extend in an arc shape, thereby effectively solving the diffraction problem and improving the display effect. Similarly, for example, the first virtual connection line D1 and the third virtual connection line D3 each may also include an arc-shaped segment.

In some embodiments, the shape of the first sub-pixel 111 is a circle.

Similar to the second virtual connection line D2, the shape of the first sub-pixel 111 may also affect the shape and size of the wiring region Z. Because the shape of the first sub-pixel 111 is a circle, a corresponding part of an outer contour of the wiring region Z is also in an arc shape. In the corresponding display panel, some wires may be arranged to extend in an arc shape, thereby effectively solving the diffraction problem and improving the display effect. Similarly, for example, the second sub-pixel 121 and the third sub-pixel 131 may also be circular.

In some embodiments, as shown in FIG. 17, the wiring region Z is in an “S” shape.

The wiring region Z is of a continuous curve structure. In the corresponding display panel, the wires may also be laid out in an S shape, thereby meeting a wiring layout requirement and achieving an effect of alleviating the diffraction problem.

In some embodiments, the wiring region Z is in an “S” shape with a constant width. That is, the width of the wiring region Z remains consistent throughout, thereby improving structural reliability of the wiring region Z, ensuring extension of the wires in the corresponding display panel within the wiring region Z, and reducing a difficulty of wire preparation.

In some embodiments, referring to FIG. 18, the first pixel group 110 includes a first non-opening region A1 arranged among the plurality of first sub-pixels 111.

The first non-opening region A1 mentioned in the embodiments of the present application means that there are no pixel openings in a region that is in the first pixel group 110 and that is among the plurality of first sub-pixels 111, i.e., there are no first sub-pixels 111 or sub-pixels of other colors. Therefore, transmittance of a position that is of the display panel and that corresponds to the first non-opening region A1 can be increased to meet a transparent display requirement.

In a conventional transparent display panel, a size of a pixel opening or the number of pixel openings is usually reduced to increase a distance between adjacent pixels, thereby increasing an area of a transparent region to meet a transparent display requirement. In the embodiments of the present application, the plurality of first sub-pixels 111 are arranged around the first virtual point, so that the first non-opening region A1 can be formed at the first virtual point, thereby concentrating the transparent region of the display panel. Compared with the conventional transparent display panel, in the embodiments of the present application, a non-opening region that can achieve a transparent effect is formed among the plurality of first sub-pixels 111 only by adjusting the pixel arrangement structure, thereby meeting the transparent display requirement and achieving effective utilization of space without changing the size of the pixel opening and a pixel density.

Similarly, in some embodiments, the second pixel group 120 includes a second non-opening region A2 arranged among the plurality of second sub-pixels 121. In some other embodiments, the third pixel group 130 includes a third non-opening region A3 arranged among the plurality of third sub-pixels 131.

In addition, in some special scenarios, based on a use requirement, a corresponding pixel circuit may be arranged in the first non-opening region A1, and an anode in the first sub-pixel 111 may be replaced with a transparent material, so that a double-sided display effect may be achieved.

In some embodiments, distances between any adjacent virtual center points O are equal.

The pixel arrangement structure includes the plurality of pixel units 100, and the virtual center point O corresponds to the central position of each pixel unit 100, i.e., a position relationship between different virtual center points O determines a position relationship between corresponding pixel units 100. Based on this, in the embodiments of the present application, the distances between any adjacent virtual center points O are set to be equal, so that relative distances between any adjacent pixel units 100 remain the same, thereby achieving regular arrangement of the plurality of pixel units 100 and helping improve the display effect.

According to some embodiments, as shown in FIG. 17 and FIG. 18, an embodiment of the present application further provides another pixel arrangement structure, including a plurality of repeatedly arranged pixel units 100. The pixel unit 100 includes a first pixel group 110, a second pixel group 120, and a third pixel group 130 around a virtual center point O. The first pixel group 110 includes a plurality of first sub-pixels 111.

The plurality of first sub-pixels 111 are spaced apart around a first virtual point to form a first transparent region centered on the first virtual point among the plurality of first sub-pixels 111. The second pixel group 120 includes a plurality of second sub-pixels 121, and the plurality of second sub-pixels 121 are spaced apart around a second virtual point to form a second transparent region centered on the second virtual point among the plurality of second sub-pixels 121. The third pixel group 130 includes a plurality of third sub-pixels 131, and the plurality of third sub-pixels 131 are spaced apart around a third virtual point to form a third transparent region centered on the third virtual point among the plurality of third sub-pixels 131.

The first pixel group 110, the second pixel group 120, and the third pixel group 130 are arranged separately to form a wiring region Z among them.

The first transparent region corresponds to a first non-opening region A1, the second transparent region corresponds to a second non-opening region A2, and the third transparent region corresponds to a third non-opening region A3. In this embodiment of the present application, the plurality of first sub-pixels 111 are arranged around the first virtual point, so that the first transparent region can be formed at the first virtual point. The plurality of second sub-pixels 121 are arranged around the second virtual point, so that the second transparent region can be formed at the second virtual point. The plurality of third sub-pixels 131 are arranged around the third virtual point, so that the third transparent region can be formed at the third virtual point. This design can achieve centralized arrangement of transparent regions in a display panel, thereby meeting a requirement for high transmittance of the corresponding display panel.

As shown in FIG. 1, in a row direction, the first sub-pixels 111, the third sub-pixels 131, and the second sub-pixels 121 are arranged in three rows respectively. Densities of the pixels in the first and third rows are the same, and a density of the pixels in the second row is twice that in the first row. The first sub-pixels 111, the third sub-pixels 131, and the second sub-pixels 121 in three consecutive rows are staggered in relation to each other and are aligned obliquely.

In a column direction, the pixels are arranged in several columns. The pixels in odd-numbered columns are arranged in the same manner, the pixels in an even-numbered column are staggered in relation to the pixels in the odd-numbered column, and an arrangement density of the pixels in the even-numbered column is twice that of the pixels in the odd-numbered column.

In addition, in this embodiment of the present application, the first pixel group 110, the second pixel group 120, and the third pixel group 130 are arranged separately to form the wiring region Z among them. Therefore, in the corresponding display panel using the pixel arrangement structure in this embodiment of the present application, a wiring structure may be arranged in the corresponding wiring region Z, to conduct a pixel circuit and meet a display requirement.

In some embodiments, the wiring region Z includes arc-shaped paths that radiate from the virtual center point toward a first direction X, a second direction Y, and a third direction Z and have the same shape. Included angles between any two of the first direction X, the second direction Y, and the third direction Z are the same, and the included angle between any two directions is 120°. For example, the arc-shaped path may alternatively be a zigzag path. In this case, a boundary between the transparent region and a non-transparent region is a straight line, for example, as indicated by the dashed line in FIG. 16.

The wiring region Z is an arc-shaped structure radiating from the virtual center point O, which is similar to a fan blade structure. The arc-shaped structures extend in the first direction X, the second direction Y, and the third direction Z. Compared with a conventional matrix wiring manner, this design uses a curved wiring form, which makes wiring more flexible and can meet a wiring requirement in a high-resolution situation. Moreover, this design can effectively solve a diffraction problem and improve a display effect.

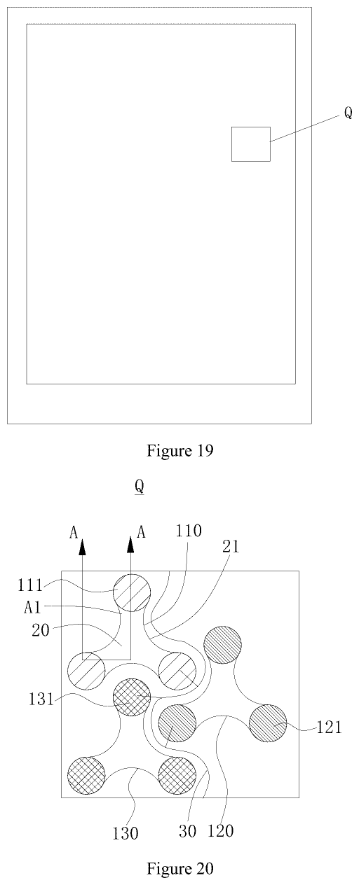

According to some embodiments, referring to FIG. 19, an embodiment of the present application provides a display panel. The display panel includes the pixel arrangement structure in any one of the above embodiments.

It should be noted that the display panel provided in this embodiment of the present application has the beneficial effects of the pixel arrangement structure in any one of the above embodiments. Reference is made to the above description of the pixel arrangement structure for details, which will not be repeated in this embodiment of the present application.

In some embodiments, referring to FIG. 20, the display panel further includes a light-transmitting material layer. The light-transmitting material layer includes a light-transmitting material portion 20. In a thickness direction of the display panel, at least part of the light-transmitting material portion 20 is located in a first pixel group 110.

The light-transmitting material portion 20 is a material with high transmittance, to improve transmittance of a corresponding position of the display panel. Based on this, at least part of the light-transmitting material portion 20 is located in the first pixel group 110. Further, at least part of the light-transmitting material portion 20 is located in a first non-opening region A1, so that a region located among a plurality of first sub-pixels 111 can have high transmittance, thereby improving the transmittance of the display panel and meeting a transparent display requirement. The light-transmitting material portion 20 may be arranged at the same layer as at least some film layers in the first sub-pixel 111, or may be located at a completely different film layer from the first sub-pixel 111. This is not limited in the embodiments of the present application.

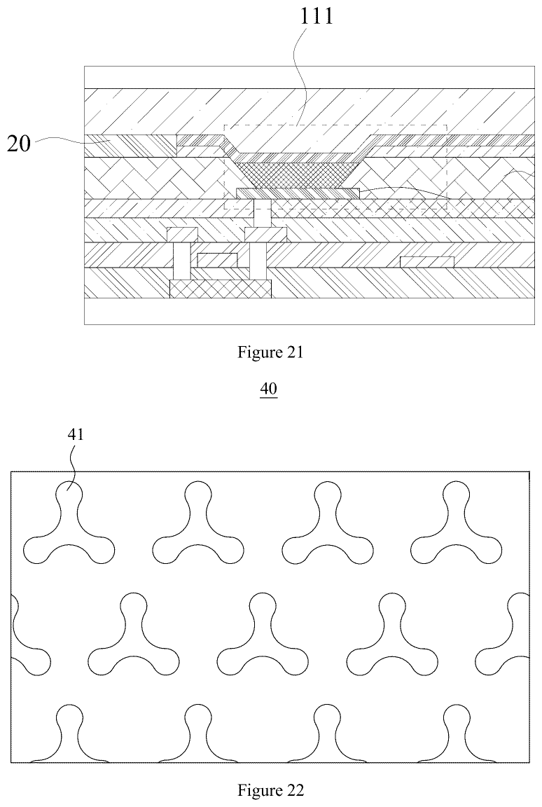

In some embodiments, referring to FIG. 21, the light-transmitting material portion 20 is arranged at the same layer as at least some film layers in the first sub-pixel 111.

The first sub-pixel 111 is formed by a variety of film layers that are stacked. For example, the first sub-pixel 111 includes a cathode layer, an anode layer, a hole injection layer, a hole transport layer, an electron injection layer, and an electron transport layer. The light-transmitting material portion 20 may be arranged at the same layer as one of the layers, thereby reducing occupation of a thickness of the display panel by the light-transmitting material layer, and facilitating a lightweight design.

In addition, in some embodiments, in the thickness direction of the display panel, at least part of the light-transmitting material portion 20 is located in at least one of a second pixel group and a third pixel group. That is, a small part of the light-transmitting material portion 20 may be located in a second non-opening region or a third non-opening region, thereby further improving the transmittance of the display panel and meeting a transparent display requirement.

In some embodiments, as shown in FIG. 20, the display panel further includes a drive wire 30 arranged between any two of the first pixel group 110, the second pixel group 120, and the third pixel group 130.

The drive wire 30 is used to control the first sub-pixel 111, the second sub-pixel 121, and the third sub-pixel 131 to implement a light-emitting function, to reduce a difficulty of arranging the drive wire 30 and reduce a risk of signal transmission delay caused by an excessive length of the drive wire 30. In the embodiments of the present application, the drive wire 30 is arranged between any two of the first pixel group 110, the second pixel group 120, and the third pixel group 130, to reduce a distance between the drive wire 30 and a corresponding sub-pixel and improve reliability of signal transmission.

In some embodiments, as shown in FIG. 20, the light-transmitting material portion 20 includes an edge portion 21, and the edge portion 21 includes an arc-shaped segment.

In order to improve a light transmission effect, it is necessary to prevent, as much as possible, the drive wire 30 and the light-transmitting material portion 20 from overlapping with each other. Therefore, the drive wire 30 is located between adjacent light-transmitting material portions 20. It can be learned from the above content that the light-transmitting material portion 20 is located among the plurality of first sub-pixels 111. Therefore, the edge portion 21 of the light-transmitting material portion 20 usually coincides with a first virtual connection line D1 connecting two first sub-pixels 111.

Based on this, in the embodiments of the present application, the edge portion 21 of the light-transmitting material portion 20 has an arc-shaped segment, so that the drive wire 30 located between the adjacent light-transmitting material portions 20 can extend in a curved form, meeting a wiring layout requirement and a light transmission requirement of the display panel. In some embodiments, the drive wire 30 may include a curved segment.

According to some embodiments, referring to FIG. 22, an embodiment of the present application provides a mask assembly. The mask assembly is configured to form the pixel arrangement structure in any one of the above embodiments through vapor deposition. The mask assembly includes a first mask 40. The first mask 40 includes a first mask opening 41 adapted to a first pixel group. The first mask opening 41 is configured as a communicating shape corresponding to all the plurality of first sub-pixels in the first pixel group.

The first mask opening 41 on the first mask 40 can correspond simultaneously to shapes and sizes of the plurality of first sub-pixels in the first pixel group. For example, when the first sub-pixel is of a circular structure, an edge of the first mask opening 41 includes an arc-shaped structure. When the first sub-pixel is of a square structure, the edge of the first mask opening 41 includes a zigzag structure.

Moreover, in the embodiments of the present application, the first mask opening 41 corresponds to a structure of the first pixel group. This design allows for simultaneous vapor deposition of the plurality of first sub-pixels in one mask opening, thereby reducing a difficulty of vapor deposition. In this embodiment, the first mask opening 41 is designed in a communicating shape that is approximately in an inverted “T” shape and corresponds to the structure of three first sub-pixels 111, to implement simultaneous vapor deposition of three sub-pixels of the same color.

Similarly, for example, the mask assembly may further include a second mask. The second mask includes a second mask opening adapted to a second sub-pixel. A plurality of second pixel openings corresponding to a plurality of second sub-pixels in a second pixel group are arranged in communication with each other. In one embodiment, the mask assembly may further include a third mask. The third mask includes a third mask opening adapted to a third sub-pixel. A plurality of third pixel openings corresponding to a plurality of third sub-pixels in a third pixel group are arranged in communication with each other.

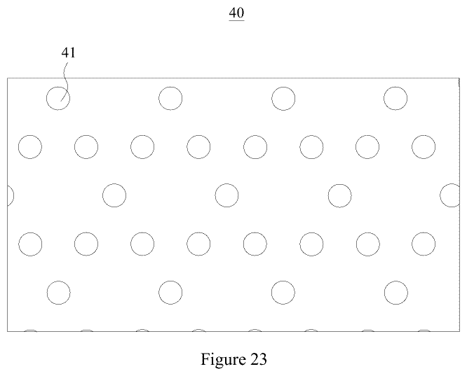

It should be noted that, in some other embodiments, referring to FIG. 23, the first mask opening 41 on the first mask 40 includes a plurality of sub-openings respectively corresponding to the plurality of first sub-pixels in the first pixel group, and the plurality of sub-openings are independent of each other, i.e., not connected as a whole. In this way, vapor deposition of a pixel material among the plurality of first sub-pixels may be avoided, thereby increasing transmittance of a region among the plurality of first sub-pixels and improving a transparent display effect.

Although the embodiments disclosed in the present application are as described above, the content described is only embodiments used to facilitate the understanding of the present application rather than to limit the present disclosure. Any modification and variation in the form and details of implementation may be made without departing from the spirit and scope disclosed in the present application, but the scope of protection of the present application shall still be subject to the scope defined by the appended claims.

The above descriptions are merely specific embodiments of the present application. For convenience and brevity of description, for replacement of other connection manners described above, reference may be made to the corresponding processes in the above method embodiments, and details are not repeated herein. It should be understood that the scope of protection of the present application is not limited thereto, any equivalent modification or replacement that can be easily conceived within the scope disclosed in the present application in the art shall fall within the scope of protection of the present application.

What is claimed is:

1. A pixel arrangement structure, comprising:
a pixel unit, wherein the pixel unit comprises a first pixel group, a second pixel group, and a third pixel group arranged around a virtual center point;
the first pixel group comprises a plurality of first sub-pixels arranged around a first virtual point,
the second pixel group comprises a plurality of second sub-pixels arranged around a second virtual point, and the third pixel group comprises a plurality of third sub-pixels arranged around a third virtual point; and
in the pixel unit, an orthographic projection of a first sub-pixel located closest to the virtual center point in a first direction is located between projections of two second sub-pixels in the first direction, and an orthographic projection of a second sub-pixel located closest to the virtual center point in a second direction is located between orthographic projections of two third sub-pixels in the second direction, wherein the first direction intersects with the second direction.

2. The pixel arrangement structure according to claim 1, wherein an orthographic projection of a third sub-pixel located closest to the virtual center point in a third direction is located between orthographic projections of two first sub-pixels in the third direction, and the first direction, the second direction, and the third direction intersect pairwise and are located in the same plane.

3. The pixel arrangement structure according to claim 2, wherein the orthographic projection of the first sub-pixel located closest to the virtual center point in the first direction is located exactly in the middle of the orthographic projections of the two second sub-pixels in the first direction;
or the orthographic projection of the second sub-pixel located closest to the virtual center point in the second direction is located exactly in the middle of the orthographic projections of the two third sub-pixels in the second direction;
or the orthographic projection of the third sub-pixel located closest to the virtual center point in the third direction is located exactly in the middle of the orthographic projections of the two first sub-pixels in the third direction;
or the first sub-pixel located closest to the virtual center point is at least partially embedded between the two second sub-pixels;
or
the second sub-pixel located closest to the virtual center point is at least partially embedded between the two third sub-pixels; or
the third sub-pixel located closest to the virtual center point is at least partially embedded between the two first sub-pixels.

4. The pixel arrangement structure according to claim 2, wherein the first sub-pixel located closest to the virtual center point, the second sub-pixel located closest to the virtual center point, and one of the third sub-pixels in the third pixel group are located on a straight line;
or
the second sub-pixel located closest to the virtual center point, the third sub-pixel located closest to the virtual center point, and one of the first sub-pixels in the first pixel group are located on a straight line;
or
the third sub-pixel located closest to the virtual center point, the first sub-pixel located closest to the virtual center point, and one of the second sub-pixels in the second pixel group are located on a straight line.

5. The pixel arrangement structure according to claim 2, wherein the first pixel group comprises three first sub-pixels, the three first sub-pixels are connected to form a first virtual triangle, and the first virtual triangle is an equilateral triangle;
or
the second pixel group comprises three second sub-pixels, the three second sub-pixels are connected to form a second virtual triangle, and the second virtual triangle is an equilateral triangle;
or
the third pixel group comprises three third sub-pixels, the three third sub-pixels are connected to form a third virtual triangle, and the third virtual triangle is an equilateral triangle.

6. The pixel arrangement structure according to claim 1, wherein at least two of the first sub-pixel located closest to the virtual center point, the second sub-pixel located closest to the virtual center point, and the third sub-pixel located closest to the virtual center point have equal distances to the virtual center point.

7. The pixel arrangement structure according to claim 5, wherein the first sub-pixel located closest to the virtual center point, the second sub-pixel located closest to the virtual center point, and the third sub-pixel located closest to the virtual center point are connected to form a fourth virtual triangle, and the fourth virtual triangle is an equilateral triangle.

8. The pixel arrangement structure according to claim 7, wherein the first virtual triangle comprises a first virtual side connecting two first sub-pixels located farther from the virtual center point, the fourth virtual triangle comprises a second virtual side connecting the second sub-pixel located closest to the virtual center point and the third sub-pixel located closest to the virtual center point, and the first virtual side and the second virtual side perpendicularly intersect at one first sub-pixel located farther from the virtual center point;
or
the first virtual triangle comprises a third virtual side connecting the first sub-pixel located closest to the virtual center point and the first sub-pixel located farther from the virtual center point, the fourth virtual triangle comprises a fourth virtual side connecting the first sub-pixel located closest to the virtual center point and the second sub-pixel located closest to the virtual center point, and a third virtual line side is perpendicular to the fourth virtual side.

9. The pixel arrangement structure according to claim 7, wherein a side length of the first virtual triangle is M, a side length of the fourth virtual triangle is N, and M and N satisfy:
M=N*√3;
or the third sub-pixel located closest to the virtual center point is located on an angle bisector of an angle of the first virtual triangle.

10. The pixel arrangement structure according to claim 5, wherein the first sub-pixel is arranged on a virtual connection line of the first virtual point and the second virtual point;
or
the second sub-pixel is arranged on a virtual connection line of the second virtual point and the third virtual point; or
the third sub-pixel is arranged on a virtual connection line of the first virtual point and the third virtual point.

11. The pixel arrangement structure according to claim 10, wherein the second sub-pixel is arranged on an extension line of the connection line of the first virtual point and the second virtual point, and the second sub-pixel is located on a side of the second virtual point facing away from the first virtual point; or
the third sub-pixel is arranged on an extension line of the connection line of the second virtual point and the third virtual point, and the third sub-pixel is located on a side of the third virtual point facing away from the second virtual point; or
the first sub-pixel is arranged on an extension line of the connection line of the first virtual point and the third virtual point, and the first sub-pixel is located on a side of the first virtual point facing away from the third virtual point.

12. The pixel arrangement structure according to claim 10, wherein a direction of a connection line of the first sub-pixel located closest to the virtual center point and the second sub-pixel located closest to the virtual center point is parallel to a direction of the connection line of the first virtual point and the third virtual point;
or a direction of a connection line of the second sub-pixel located closest to the virtual center point and the third sub-pixel located closest to the virtual center point is parallel to a direction of the connection line of the first virtual point and the second virtual point;
or a direction of a connection line of the first sub-pixel located closest to the virtual center point and the third sub-pixel located closest to the virtual center point is parallel to a direction of the connection line of the second virtual point and the third virtual point.

13. The pixel arrangement structure according to claim 1, wherein the first pixel group comprises four first sub-pixels, and the four first sub-pixels are connected to form a first virtual quadrilateral;
the first virtual quadrilateral is a parallelogram;
or the first virtual quadrilateral is a rectangle;
or the first virtual quadrilateral is a square.

14. The pixel arrangement structure according to claim 1, wherein the first pixel group, the second pixel group and the third pixel group are separated from each other to form a wiring area between any two of the first pixel group, the second pixel group and the third pixel group.

15. The pixel arrangement structure according to claim 14, wherein the second pixel group comprises a second virtual connection line connecting the two second sub-pixels, and the first sub-pixel located closest to the virtual center point is spaced apart from the second virtual connection line, to form at least part of a wiring region between the first sub-pixel and the second virtual connection line; and
the second virtual connection line comprises an arc-shaped segment, a shape of the first sub-pixel is a circle, and the wiring region is in an “S” shape.

16. The pixel arrangement structure according to claim 1, wherein the first pixel group comprises a first non-opening region arranged among the plurality of the first sub-pixels;
or
the second pixel group comprises a second non-opening region arranged among the plurality of the second sub-pixels;
or
the third pixel group comprises a third non-opening region arranged among the plurality of the third sub-pixels;
or distances between any two adjacent virtual center points are equal.

17. A pixel arrangement structure, comprising a plurality of repeatedly arranged pixel units, wherein the pixel unit comprises a first pixel group, a second pixel group, and a third pixel group around a virtual center point;
the first pixel group comprises a plurality of first sub-pixels, and the plurality of first sub-pixels are spaced apart around a first virtual point to form a first transparent region centered on the first virtual point among the plurality of first sub-pixels;
the second pixel group comprises a plurality of second sub-pixels, and the plurality of second sub-pixels are spaced apart around a second virtual point to form a second transparent region centered on the second virtual point among the plurality of second sub-pixels;
the third pixel group comprises a plurality of third sub-pixels, and the plurality of third sub-pixels are spaced apart around a third virtual point to form a third transparent region centered on the third virtual point among the plurality of third sub-pixels; and
the first pixel group, the second pixel group and the third pixel group are separated from each other to form a wiring area between any two of the first pixel group, the second pixel group and the third pixel group.

18. The pixel arrangement structure according to claim 17, wherein a wiring region comprises arc-shaped paths that radiate from the virtual center point toward a first direction, a second direction, and a third direction and have the same shape;
angles between any two of the first direction, the second direction, and the third direction are the same;
or
the wiring region comprises a zigzag path.

19. A display panel, comprising the pixel arrangement structure according to claim 1.

20. The display panel according to claim 19, further comprising a light-transmitting material layer, wherein the light-transmitting material layer comprises a light-transmitting material portion, and in a thickness direction of the display panel, at least part of the light-transmitting material portion is located in the first pixel group;
the light-transmitting material portion is arranged at the same layer as at least some film layers in the first sub-pixel;
in the thickness direction of the display panel, at least part of the light-transmitting material portion is located in at least one of the second pixel group and the third pixel group;
the display panel further comprises a drive wire arranged between any two of the first pixel group, the second pixel group, and the third pixel group; and
the light-transmitting material portion comprises an edge portion, the edge portion comprises an arc-shaped segment, and the drive wire comprises a curved segment.
